(19) United States
(12) Patent Application Publication
(10) Pub. No.: US 2024/0364076 A1
(43) Pub. Date: Oct. 31, 2024

(54) LASER SYSTEM AND ELECTRONIC DEVICE MANUFACTURING METHOD

(71) Applicant: Gigaphoton Inc., Tochigi (JP)

(72) Inventors: Chen QU, Oyama-shi (JP); Taisuke MIURA, Oyama-shi (JP)

(73) Assignee: Gigaphoton Inc., Tochigi (JP)

(21) Appl. No.: 18/766,837

(22) Filed: Jul. 9, 2024

Related U.S. Application Data
(63) Continuation of application No. PCT/JP2022/006812, filed on Feb. 21, 2022.

(51) Int. Cl. H01S 5/06; H01S 5/065; H01S 5/50

(52) U.S. Cl. CPC H01S 5/0611; H01S 5/0654; H01S 5/50

(57) ABSTRACT

A laser system includes a first semiconductor laser device configured to output first CW laser light, a first semiconductor optical amplification device configured to amplify the first CW laser light and output second CW laser light, an optical parametric amplification device configured to amplify the second CW laser light and output first pulse laser light, and a wavelength conversion device configured to perform wavelength conversion on the first pulse laser light and output second pulse laser light in a deep ultraviolet wavelength region.

### CROSS-REFERENCE TO RELATED APPLICATIONS

The present application claims the benefit of International Application No. PCT/JP2022/006812, filed on Feb. 21, 2022, the entire contents of which are hereby incorporated by reference.

### BACKGROUND

### 1. Technical Field

The present disclosure relates to a laser system and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2007-86108
Patent Document 2: Japanese Patent Application Publication No. 2002-223018
Patent Document 3: Japanese Patent Application Publication No. 2004-86193
Patent Document 4: U.S. patent Ser. No. 10/095,084
Patent Document 5: U.S. Pat. No. 7,593,437

### SUMMARY

A laser system according to an aspect of the present disclosure includes a first semiconductor laser device configured to output first CW laser light, a first semiconductor optical amplification device configured to amplify the first CW laser light and output second CW laser light, an optical parametric amplification device configured to amplify the second CW laser light and output first pulse laser light, and a wavelength conversion device configured to perform wavelength conversion on the first pulse laser light and output second pulse laser light in a deep ultraviolet wavelength region.

An electronic device manufacturing method according to another aspect of the present disclosure includes generating laser light using a laser system, outputting the laser light to an exposure apparatus, and exposing a photosensitive substrate to the laser light in the exposure apparatus to manufacture an electronic device. Here, the laser system includes a first semiconductor laser device configured to output first CW laser light, a first semiconductor optical amplification device configured to amplify the first CW laser light and output second CW laser light, an optical parametric amplification device configured to amplify the second CW laser light and output first pulse laser light, and a wavelength conversion device configured to perform wavelength conversion on the first pulse laser light and output second pulse laser light in a deep ultraviolet wavelength region.

### BRIEF DESCRIPTION OF THE DRAWINGS

Embodiments of the present disclosure will be described below merely as examples with reference to the accompanying drawings.

FIG. 1 schematically shows the configuration of a laser system according to a comparative example.

FIG. 2 schematically shows the configuration of a solid state laser system according to the comparative example.

FIG. 3 is a graph showing an example of a spectrum of laser light output from the solid state laser system according to the comparative example.

FIG. 4 is a graph showing an example of values of the E95 line width when CW laser light is pulsed using a semiconductor optical amplifier.

FIG. 5 schematically shows the configuration of the solid state laser system according to a first embodiment.

FIG. 6 schematically shows the configuration of a specific example of the optical parametric amplification device.

FIG. 7 schematically shows a configuration example of a wavelength conversion device.

FIG. 8 is a graph showing an example of the spectrum of deep ultraviolet light output from the solid state laser system according to the first embodiment.

FIG. 9 is a graph showing an example of values of the E95 line width of deep ultraviolet light output from the solid state laser system according to the first embodiment.

FIG. 10 schematically shows the configuration of the solid state laser system according to a second embodiment.

FIG. 11 is a graph showing an example of a multiplexed spectrum.

FIG. 12 schematically shows the configuration of the solid state laser system according to a third embodiment.

FIG. 13 schematically shows a configuration example of an exposure apparatus.

### DESCRIPTION OF EMBODIMENTS

### <Contents>

1. Overview of laser system according to comparative example
   1.1 Configuration
   1.2 Operation
   1.3 Configuration of solid state laser system
   1.4 Operation of solid state laser system
   1.5 Problem
2. First embodiment
   2.1 Configuration
   2.2 Operation
   2.3 Example of optical parametric amplification device
      2.3.1 Configuration
      2.3.2 Operation
      2.3.3 Modification
   2.4 Example of wavelength conversion device
   2.5 Effect
3. Second Embodiment
   3.1 Configuration
   3.2 Operation
   3.3 Effect
4. Third Embodiment
   4.1 Configuration
   4.2 Operation
   4.3 Effect
5. Modification of excimer amplification device
6. Electronic device manufacturing method
7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview of Laser System According to Comparative Example

### 1.1 Configuration

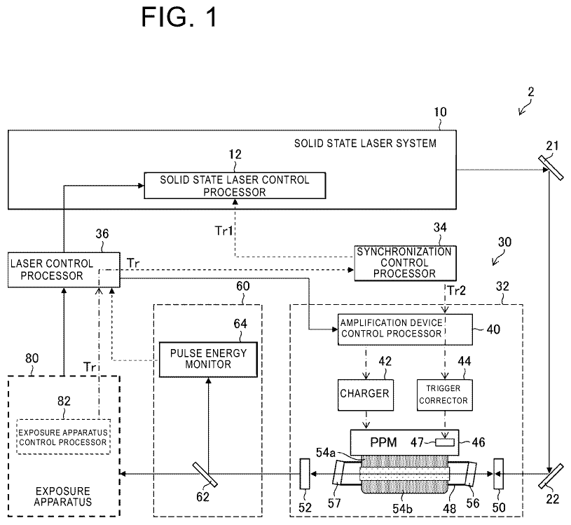

FIG. 1 schematically shows the configuration of a laser system 2 according to a comparative example. The comparative example of the present disclosure is an example recognized by the applicant as known only by the applicant, and is not a publicly known example admitted by the applicant.

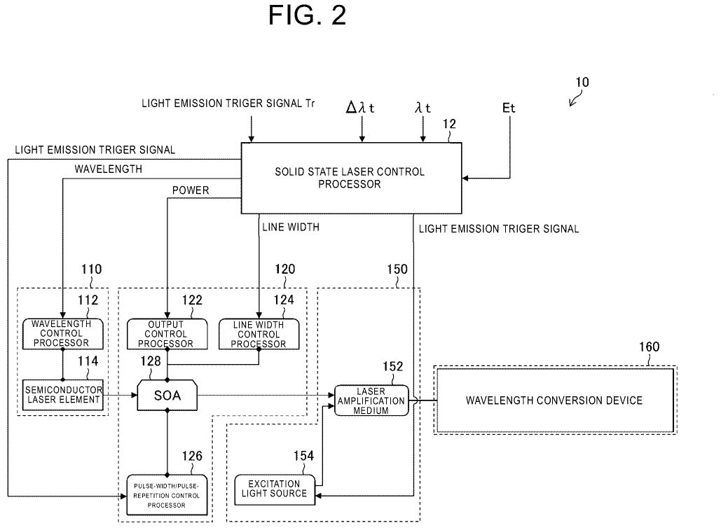

The laser system 2 includes a solid state laser system 10, high reflection mirrors 21, 22, an excimer system 30, and a monitor module 60. The detailed configuration of the solid state laser system 10 will be described later with reference to FIG. 2. The excimer system 30 includes an excimer amplification device 32, a synchronization control processor 34, and a laser control processor 36. The processor in the present disclosure is a processing device including a storage device in which a control program is stored and a central processing unit (CPU) that executes the control program. The processor is specifically configured or programmed to perform various processes included in the present disclosure.

The excimer amplification device 32 includes an amplification device control processor 40, a charger 42, a trigger corrector 44, a pulse power module (PPM) 46, a chamber 48, a partial reflection mirror 50, and an output coupling mirror 52. The partial reflection mirror 50 and the output coupling mirror 52 configure an optical resonator, and the chamber 48 is arranged on the optical path of the optical resonator.

For example, a KrF laser gas including a Kr gas, an F₂ gas, and an Ne gas is introduced into the chamber 48. The laser gas may be an ArF laser gas including an Ar gas, an F₂ gas, and an Ne gas. A pair of discharge electrodes 54a, 54b are arranged in the chamber 48, and the discharge electrodes 54a, 54b are connected to output terminals of the PPM 46.

Two windows 56, 57 through which KrF laser light is transmitted are arranged at the chamber 48. The PPM 46 includes a switch 47, a pulse transformer (not shown), and a magnetic switch. The monitor module 60 includes a beam splitter 62 and a pulse energy monitor 64.

The beam splitter 62 is arranged on the optical path of pulse laser light output from the excimer amplification device 32, and is arranged such that pulse laser light reflected by the beam splitter 62 enters the pulse energy monitor 64. The pulse energy monitor 64 detects the pulse energy of ultraviolet light. The pulse energy monitor 64 may be a pulse energy sensor including, for example, a photodiode or a pyroelectric element. Information detected by the pulse energy monitor 64 is transmitted to the laser control processor 36.

The laser control processor 36 is connected to the solid state laser control processor 12, the synchronization control processor 34, the amplification device control processor 40, and an exposure apparatus control processor 82 of an exposure apparatus 80.

### 1.2 Operation

The laser control processor 36 receives a target pulse energy Et, a target center wavelength λt, and a light emission trigger signal Tr from the exposure apparatus control processor 82 of the exposure apparatus 80. Further, the laser control processor 36 transmits and receives data to and from the exposure apparatus control processor 82 as necessary, and notifies the exposure apparatus control processor 82 of an exposure NG signal. The exposure NG signal is a signal indicating that preparation of the laser system 2 is not completed and exposure cannot be performed. The laser control processor 36 may generate an internal trigger signal at a predetermined repetition frequency to substitute the light emission trigger signal Tr.

The light emission trigger signal Tr is input to the synchronization control processor 34 via the laser control processor 36. The synchronization control processor 34 outputs, in synchronization with the light emission trigger signal Tr output from the exposure apparatus control processor 82 or the internal trigger signal, a trigger signal Tr1 to the solid state laser control processor 12 of the solid state laser system 10 and a trigger signal Tr2 for causing the excimer amplification device 32 to synchronously discharge.

Pulse laser light having a center wavelength of 248.35 nm output from the solid state laser system 10 enters the excimer amplification device 32 via the high reflection mirror 21 and the high reflection mirror 22. In synchronization with the injection of pulse laser light having a wavelength of 248.35 nm, the excimer amplification device 32 generates a population inversion by discharge. Here, the numerical value of the wavelength described in the present specification is an example of a representative value, and without being limited to the numerical value of the wavelength described, may be a value of a wavelength in the vicinity of the numerical value of the wavelength. For example, a wavelength of 248.35 nm includes the meaning of a wavelength about 248.35 nm unless otherwise specified.

The trigger corrector 44 adjusts the timing for the switch 47 of the PPM 46 so that pulse laser light output from the solid state laser system 10 is efficiently amplified by the excimer amplification device 32. Accordingly, amplified pulse laser light is output from the excimer amplification device 32. Pulse laser light amplified by the excimer amplification device 32 enters the monitor module 60, a part thereof is reflected by the beam splitter 62 to enter the pulse energy monitor 64, and a pulse energy E is measured.

The laser control processor 36 acquires information of the pulse energy E measured by the pulse energy monitor 64, and calculates a difference ΔE between the pulse energy E and the target pulse energy Et. The laser control processor 36 controls a charge voltage Vhv of the charger 42 via the amplification device control processor 40 so that ΔE approaches 0. The laser control processor 36 determines whether ΔE is a value within an allowable range, and when ΔE is within the allowable range, stops outputting the internal trigger signal from the laser control processor 36, and notifies the exposure apparatus control processor 82 of an exposure OK signal. The exposure OK signal is a signal indicating that preparation of the laser system 2 is completed and exposure can be performed.

Upon receiving the exposure OK signal from the laser control processor 36, the exposure apparatus control processor 82 transmits the light emission trigger signal Tr to the laser control processor 36.

As a result, pulse laser light is output from the laser system 2 within the respective allowable ranges of the target center wavelength λt (e.g., λt=248.35 nm) and the target pulse energy Et. Pulse laser light output from the laser system 2 enters the exposure apparatus 80, and an exposure process is performed.

Upon receiving data of a new target center wavelength λt, target pulse energy Et, and target spectral line width Δλt from the exposure apparatus control processor 82, the laser control processor 36 transmits the data to the solid state laser control processor 12.

Even when the light emission trigger signal Tr is not received, the solid state laser control processor 12 generates the internal trigger signal and controls the semiconductor laser device 110 (see FIG. 2) of the solid state laser system 10 in advance so as to realize the target center wavelength λt, the target pulse energy Et, and the target spectral line width Δλt.

### 1.3 Configuration of Solid State Laser System

FIG. 2 schematically shows the configuration of the solid state laser system 10 applied to the laser system 2. The solid state laser system 10 includes the solid state laser control processor 12, a wavelength tunable semiconductor laser device 110, a semiconductor optical amplification device 120, a laser amplification device 150, and a wavelength conversion device 160. The semiconductor laser device 110 includes a wavelength control processor 112 and a semiconductor laser element 114.

The semiconductor optical amplification device 120 includes an output control processor 122, a line width control processor 124, a pulse-width/pulse-repetition control processor 126, and a semiconductor optical amplifier (SOA) 128.

The laser amplification device 150 includes a laser amplification medium 152 and an excitation light source 154. The laser amplification medium 152 may be, for example, a solid state laser medium such as Cr:YAG or Tm:YAP, or an optical parametric amplifier (OPA) crystal such as an LN (lithium niobate (LiNbO₃)) crystal or a KTP (KTiOPO₄) crystal. The excitation light source 154 may be a semiconductor laser or a solid state laser.

Although details of the wavelength conversion device 160 are not shown in FIG. 2, the wavelength conversion device 160 may be configured to include, for example, a first LBO crystal, a second LBO crystal, and a CLBO crystal. LBO is represented by the chemical formula LiB₃O₅. CLBO is represented by the chemical formula CsLiB₆O₁₀. Each of the LBO crystal and the CLBO crystal is a nonlinear crystal for wavelength conversion. The term “nonlinear crystal” is synonymous with “nonlinear optical crystal.” In place of the LBO crystal, an LN crystal, a KTP crystal, or a BBO (Beta barium borate (BBO)) crystal may be used. Further, in place of the CLBO crystal, a BBO crystal may be used.

### 1.4 Operation of Solid State Laser System

Upon receiving the light emission trigger signal Tr and instruction of the target line width, the target wavelength, and the target pulse energy from an external apparatus such as the exposure apparatus 80, the solid state laser control processor 12 controls the light emission trigger signal, the wavelength, the power, the line width, and the pulse width for the laser system 2.

The semiconductor laser element 114 generates continuous wave (CW) laser light of a single longitudinal mode in the near infrared wavelength region with a CW current applied thereto. The semiconductor laser element 114 may be, for example, a distributed feedback (DFB) laser or a distributed bragg reflector (DBR) laser.

The wavelength control processor 112 adjusts the temperature of and the application current to the semiconductor laser element 114 in accordance with the wavelength instruction from the solid state laser control processor 12.

The semiconductor optical amplifier 128 converts CW light into pulse light by the applied pulse current. The output control processor 122 adjusts the peak current value of the pulse current applied to the semiconductor optical amplifier 128 in accordance with the power instruction from the solid state laser control processor 12. The line width control processor 124 adjusts the rising time of the pulse current applied to the semiconductor optical amplifier 128 in accordance with the line width instruction from the solid state laser control processor 12. The pulse-width/pulse-repetition control processor 126 adjusts the pulse width and the repetition frequency of the pulse current applied to the semiconductor optical amplifier 128 in accordance with the light emission trigger signal from the solid state laser control processor 12.

The laser amplification device 150 amplifies light converted into pulse light. The excitation light source 154 emits excitation light in accordance with the light emission trigger signal from the solid state laser control processor 12.

The wavelength conversion device 160 generates light in the deep ultraviolet wavelength region from the near infrared light amplified by the laser amplification device 150 using a plurality of nonlinear optical crystals.

### 1.5 Problem

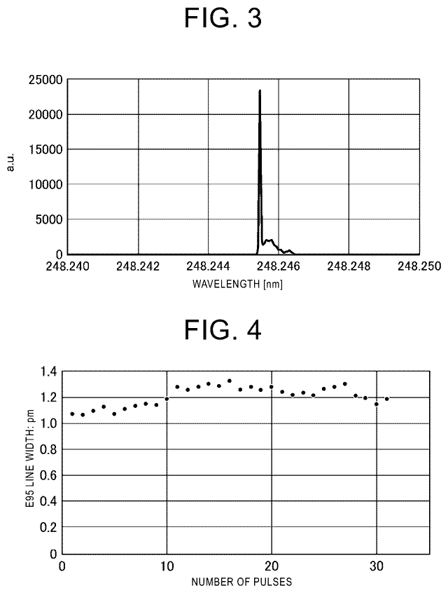

FIG. 3 is an example of a spectral waveform of laser light output from the solid state laser system 10 according to the comparative example. When CW laser light is pulsed using the semiconductor optical amplification device 120, a tail appears in the spectrum due to ringing (oscillation) of the pulse current applied to the semiconductor optical amplifier 128. The spectral waveform shown in FIG. 3 has a half width (FW 50%) of 0.0527 pm and an E95 line width of 1.3286 pm. The E95 line width refers to the spectral line width of a part that accounts for 95% of the total spectral energy. When pulsing is performed using the semiconductor optical amplifier 128, since tail components of the spectrum vary among pulses, variation in the E95 line width increases (see FIG. 4).

FIG. 4 is a graph showing values of the E95 line width plotted for each pulse when CW laser light is pulsed using the semiconductor optical amplifier 128. The horizontal axis represents the number of pulses and the vertical axis represents the E95 line width. As shown in FIG. 4, the E95 line width varies among pulses, with an average E95 line width of 1.206619 and a standard deviation σ of 0.076687 for the 30 pulses shown.

### 2. First Embodiment

### 2.1 Configuration

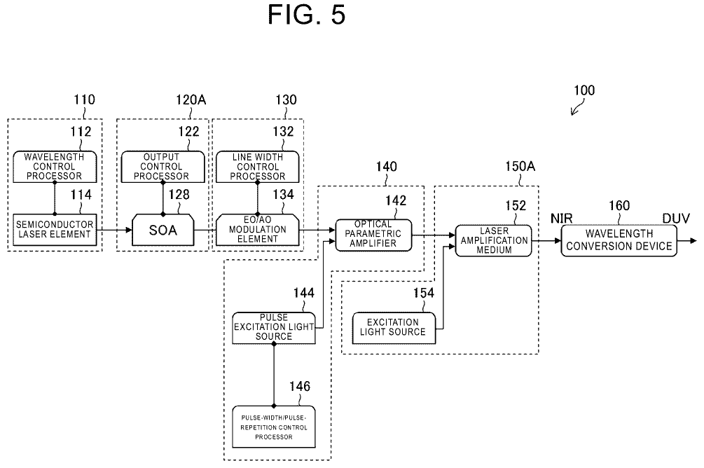

FIG. 5 schematically shows the configuration of the solid state laser system 100 according to a first embodiment. The solid state laser system 100 shown in FIG. 5 will be described in terms of differences from the configuration shown in FIG. 2. The solid state laser system 100 includes a semiconductor optical amplification device 120A that amplifies and outputs CW laser light output from the semiconductor laser device 110 in place of the semiconductor optical amplification device 120 of FIG. 2. Further, in the solid state laser system 100, an EO/AO modulation device 130 and an optical parametric amplification device 140 are arranged downstream the semiconductor optical amplification device 120A, and a laser amplification device 150A is arranged downstream the optical parametric amplification device 140.

The EO/AO modulation device 130 includes a line width control processor 132 and an EO/AO modulation element 134. The notation of EO/AO means electro-optic (EO) or acousto-optic (AO). The EO/AO modulation device 130 is an EO modulation device or an AO modulation device. An EO modulation element is configured using, for example, an LN crystal. An AO modulation element is configured using, for example, synthetic quartz or a quartz crystal. Although FIG. 5 shows an example in which the EO/AO modulation element 134 is arranged downstream the semiconductor optical amplifier 128, the EO/AO modulation element 134 may be arranged upstream the semiconductor optical amplifier 128.

The optical parametric amplification device 140, also referred to as a pulse slicer, includes an optical parametric amplifier (OPA) 142 as a pulse slice element, a pulse excitation light source 144, and a pulse-width/pulse-repetition control processor 146. The optical parametric amplifier 142 is configured using an optical parametric crystal such as a periodically poled lithium niobate (PPLN) crystal or a KTP (KTiOPO₄) crystal. The pulse excitation light source 144 may be a solid state laser using, for example, Yb:YAG, Yb:YVO₄, Nd:YAG, Nd:YVO₄, Yb:YGAG (Yb:Y₃Ga₂Al₃O₁₂), Yb:KGW, Yb:KYW, Yb:Y₂O₃, or Nd:YLF as a laser amplification medium, or may be a fiber laser using a Yb doped fiber or the like.

The laser amplification device 150A may be, for example, an optical parametric amplification device, a solid state laser amplification device using Cr:YAG, Tm:YAP, or the like, or a fiber amplification device using a fluoride fiber, a Raman fiber, or the like. The excitation light source 154 of the laser amplification device 150A may be a CW excitation light source that outputs CW excitation light.

Other configurations may be similar to those of FIGS. 1 and 2. The solid state laser system 100 is an example of the “laser system” in the present disclosure. The semiconductor laser device 110 is an example of the “first semiconductor laser device” in the present disclosure. The CW laser light, which is CW near infrared light output from the semiconductor laser element 114, is an example of the “first CW laser light” in the present disclosure. The semiconductor optical amplification device 120A is an example of the “first semiconductor optical amplification device” in the present disclosure. The laser amplification device 150A is an example of the “amplification device” in the present disclosure.

### 2.2 Operation

The semiconductor optical amplifier 128 configuring the semiconductor optical amplification device 120A adjusts the output of CW near infrared light with the CW current from the output control processor 122. The EO/AO modulation element 134 adjusts the spectral line width of CW near infrared light with a radio frequency (RF) current from the line width control processor 132.

The optical parametric amplification device 140 generates near infrared light being pulse light from CW near infrared light with pulse excitation light from the pulse excitation light source 144. The time width of pulse light generated by the optical parametric amplification device 140 is adjusted by the pulse width of excitation light. The pulse-width/pulse-repetition control processor 146 adjusts the pulse width and the pulse repetition frequency of the excitation light supplied to the optical parametric amplifier 142 with the pulse current.

CW laser light, which is CW near infrared light output from the semiconductor optical amplifier 128, is an example of the “second CW laser light” in the present disclosure. Pulse light (pulse laser light) output from the optical parametric amplifier 142 is an example of the “first pulse laser light” in the present disclosure.

### 2.3 Example of Optical Parametric Amplification Device

### 2.3.1 Configuration

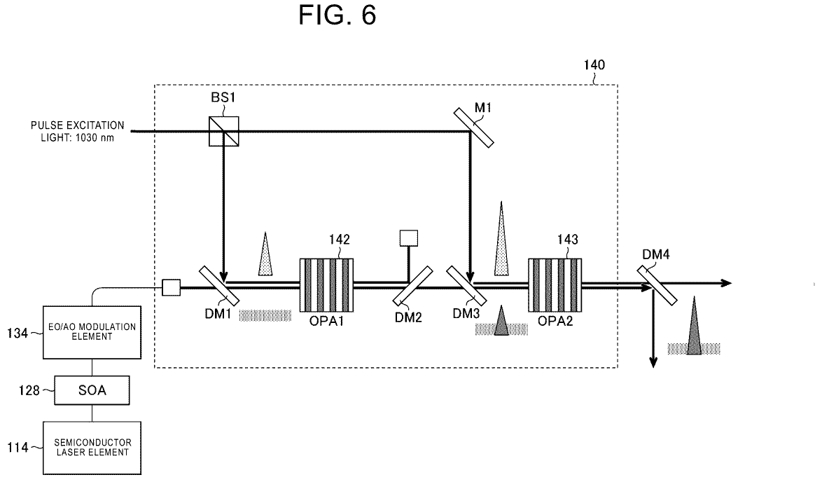

FIG. 6 schematically shows the configuration of a specific example of the optical parametric amplification device 140. Seed light to enter the optical parametric amplification device 140 is generated using the semiconductor laser element 114 being wavelength tunable in CW operation, the semiconductor optical amplifier 128, and the EO/AO modulation element 134. The optical parametric amplification device 140 includes an optical parametric amplifier 142 as a pulse slice element. A second optical parametric amplifier 143 may be further arranged at a subsequent stage of the optical parametric amplifier 142. The laser amplification medium of each of the optical parametric amplifier 142 and the optical parametric amplifier 143 may be, for example, a PPLN crystal, a periodically poled KTP (PPKTP) crystal, or a bulk crystal of, for example, LN or KTP having no periodicity. The optical parametric amplifier 142 and the optical parametric amplifier 143 may be crystals of the same type or crystals of different types.

The optical parametric amplification device 140 includes a beam splitter BS1, a total reflection mirror Ml, and a plurality of dichroic mirrors DM1, DM2, DM3. The beam splitter BS1 is arranged on the optical path of pulse excitation light from the pulse excitation light source 144. The beam splitter BS1 is an example of the “branch optical system” in the present disclosure.

The dichroic mirror DM1 is arranged such that the optical axis of excitation light reflected by the beam splitter BS1 and the optical axis of seed light pulsed by the EO/AO modulation element 134 coincide with each other, and excitation light and seed light enter the optical parametric amplifier 142. The dichroic mirror DM2 is arranged between the optical parametric amplifier 142 and the dichroic mirror DM3.

The total reflection mirror Ml is arranged such that excitation light transmitted through the beam splitter BS1 is reflected and reflection light is incident on the dichroic mirror DM3. The dichroic mirror DM3 is arranged such that the optical axis of pulse light in the near infrared wavelength region transmitted through the dichroic mirror DM2 and the optical axis of excitation light reflected by the total reflection mirror Ml coincide with each other, and pulse near infrared (NIR) light and excitation light enter the optical parametric amplifier 143.

A dichroic mirror DM4 is arranged downstream the optical parametric amplifier 143. The dichroic mirror DM4 may be included in the optical parametric amplification device 140.

### 2.3.2 Operation

The beam splitter BS1 branches excitation light into two. Each of excitation light reflected by the beam splitter BS1 and excitation light transmitted through the beam splitter BS1 is an example of the “branched light” in the present disclosure. Excitation light reflected by the beam splitter BS1 is incident on the dichroic mirror DM1. Excitation light transmitted through the beam splitter BS1 is incident on the total reflection mirror Ml. The total reflection mirror Ml reflects excitation light so as to guide excitation light transmitted through the beam splitter BS1 to the optical parametric amplifier 143.

The wavelength tunable semiconductor laser element 114 generates CW NIR light. The semiconductor optical amplifier 128 adjusts the intensity of CW NIR light. CW NIR light whose spectral line width is adjusted by the EO/AO modulation element 134 is incident on the dichroic mirror DM1.

The dichroic mirror DM1 transmits NIR light, reflects excitation light, aligns the optical axes of the both, and guides NIR light and excitation light to the optical parametric amplifier 142.

The optical parametric amplifier 142 generates, from CW NIR light, pulse light (pulse NIR light) having substantially the same pulse width as excitation light by optical parametric amplification. The dichroic mirror DM2 transmits pulse NIR light and reflects excitation light to separate the both.

The dichroic mirror DM3 transmits pulse NIR light transmitted through the dichroic mirror DM2, reflects excitation light reflected by the total reflection mirror Ml, aligns the optical axis of the both, and guides pulse NIR light and excitation light to the optical parametric amplifier 143.

The optical parametric amplifier 143 amplifies pulse NIR light by optical parametric amplification. The dichroic mirror DM4 reflects the amplified pulse NIR light and transmits excitation light to separate the both.

### 2.3.3 Modification

In FIG. 6, the optical parametric amplification device 140 having a two-stage configuration in which pulse amplification is performed in two stages by using the optical parametric amplifier 142 and the optical parametric amplifier 143 is exemplified, but not limited to the two-stage configuration, a multi-stage configuration in which amplification is performed in stages more than two such as a three-stage configuration may be employed.

Further, not limited to the multi-stage configuration, for example, a configuration (one-stage configuration) in which the optical parametric amplifier 143 at the subsequent stage in FIG. 6 is omitted and pulse amplification is performed by the optical parametric amplifier 142 may be employed. Here, the total reflection mirror may be used in place of the beam splitter BS1, and the total reflection mirror Ml and the dichroic mirrors DM3, DM4 may be omitted.

### 2.4 Example of Wavelength Conversion Device

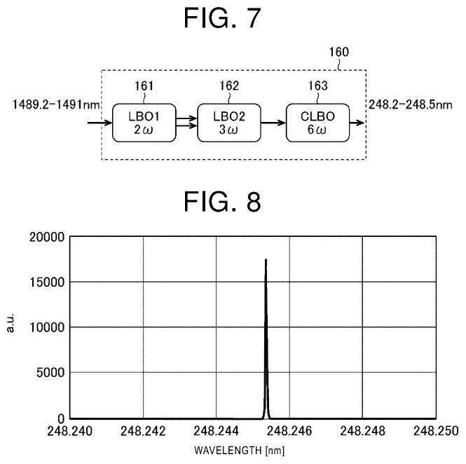

FIG. 7 schematically shows a configuration example of the wavelength conversion device 160. The wavelength conversion device 160 includes, for example, a first LBO crystal 161, a second LBO crystal 162, and a CLBO crystal 163. In place of the LBO crystals, LN crystals, KTP crystals, or BBO (β-BaB₂O₄) crystals may be used. In place of the CLBO crystal, a BBO crystal may be used. In the drawings, for example, the first LBO crystal 161 is represented as “LBO1.”

NIR light output from the wavelength tunable semiconductor laser device 110, pulsed through the semiconductor optical amplification device 120A, the EO/AO modulation device 130, and the optical parametric amplification device 140, and amplified by the laser amplification device 150A is incident on the first LBO crystal 161 of the wavelength conversion device 160. The wavelength conversion device 160 generates a second harmonic (2ω) of NIR light using the first LBO crystal 161, generates a third harmonic (3ω) from the second harmonic and NIR light using the second LBO crystal 162, and generates a sixth harmonic (6ω) in the deep ultraviolet wavelength region using the CLBO crystal 163 from the third harmonic.

The wavelength of NIR light entering the wavelength conversion device 160 may be, for example, in a range of 1489.2 nm to 1491 nm. Further, the wavelength of deep ultraviolet (DUV) light output from the wavelength conversion device 160 may be, for example, in a range of 248.2 nm to 248.5 nm. Pulse laser light, which is DUV light, output from the wavelength conversion device 160, is an example of the “second pulse laser light” in the present disclosure.

### 2.5 Effect

The wavelength of DUV light output from the solid state laser system 100 according to the first embodiment is adjusted by controlling the temperature of and the current value to of the semiconductor laser element 114. The pulse energy of DUV light output from the solid state laser system 100 is adjusted by power control of the semiconductor optical amplifier 128. The spectral line width of DUV light output from the solid state laser system 100 is adjusted by line width control of the EO/AO modulation element 134. The pulse width and the pulse repetition frequency of DUV light output from the solid state laser system 100 are adjusted by the pulse width and the pulse repetition frequency of excitation light supplied to the optical parametric amplifier 142 of the optical parametric amplification device 140.

According to the solid state laser system 100 of the first embodiment, the target of each of the wavelength, the pulse energy, the spectral line width, the pulse width, and the repetition frequency can be independently controlled.

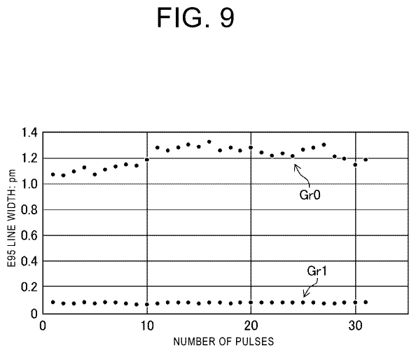

Since the optical parametric amplifier 142 pulses CW light by excitation with pulse light instead of with the pulse current, generation of tail components of the spectrum caused by ringing or the like of the pulse current described in FIGS. 2 and 3 is suppressed, so that DUV light having a narrow E95 line width can be generated (see FIG. 8). Further, since DUV light generated by the solid state laser system 100 according to the present embodiment has almost no tail components in the spectrum, the variation in the E95 line width per pulse is also small, and the stability of the spectral line width is excellent (see FIG. 9).

FIG. 8 is a graph showing an example of the spectrum of DUV light output from the solid state laser system 100. As is apparent from the comparison between FIG. 3 and FIG. 8, the spectrum of DUV light shown in FIG. 8 has almost no tail components due to ringing.

FIG. 9 is a graph showing an example of a change in the E95 line width of DUV light output from the solid state laser system 100 according to the first embodiment. For comparison, FIG. 9 also shows a graph Gr0 showing a change in the E95 line width of DUV light output from the solid state laser system 10 according to the comparative example described in FIG. 4.

As is apparent from the comparison between a graph Gr1 in which the E95 line width of DUV light output from the solid state laser system 100 according to the first embodiment is plotted for each pulse and the graph Gr0 of the comparative example, DUV light output from the solid state laser system 100 according to the first embodiment has a narrow E95 line width and a small variation in the E95 line width.

Here, the average value of the E95 line width of DUV light output from the solid state laser system 100 according to the first embodiment shown as the graph Gr1 is 0.078645, and the standard deviation σ is 0.003905.

### 3. Second Embodiment

### 3.1 Configuration

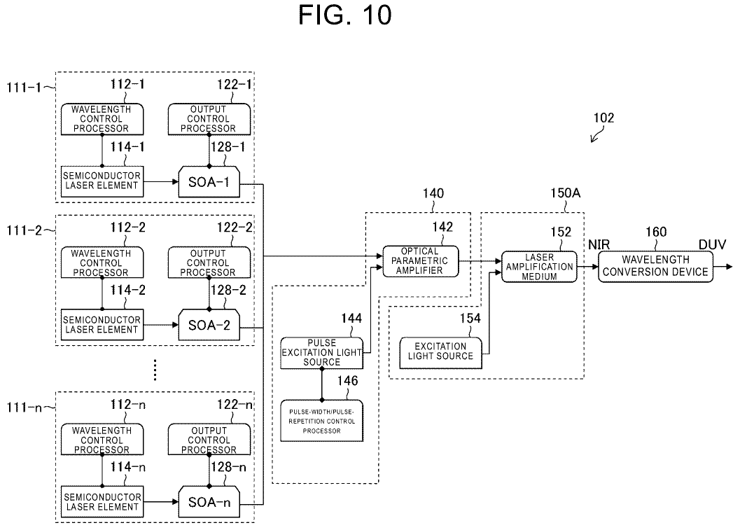

FIG. 10 schematically shows the configuration of a solid state laser system 102 according to a second embodiment. The configuration shown in FIG. 10 will be described in terms of differences from the configuration shown in FIG. 5. The solid state laser system 102 shown in FIG. 10 includes a plurality of wavelength tunable semiconductor laser modules 111-1, 111-2, . . . , 111-n each having a wavelength tunable semiconductor laser device and a semiconductor optical amplification device modularized, in place of the wavelength tunable semiconductor laser device 110, the semiconductor optical amplification device 120A, and the EO/AO modulation device 130 of the solid state laser system 100 shown in FIG. 5. Hereinafter, the wavelength tunable semiconductor laser module 111-k will be described with a module number k. Here, k is an integer satisfying 1≤k≤n. Further, n represents the number of modules and may be any integer equal to or greater than 2.

Each wavelength tunable semiconductor laser module 111-k (k=1, 2, . . . , n) includes a wavelength control processor 112-k, a wavelength tunable semiconductor laser element 114-k, an output control processor 122-k, and a semiconductor optical amplifier 128-k.

CW NIR light output from the semiconductor optical amplifier 128-k of the wavelength tunable semiconductor laser module 111-k is input to the optical parametric amplification device 140. The configurations of the optical parametric amplification device 140, the laser amplification device 150A, and the wavelength conversion device 160 included in the solid state laser system 102 may be similar to those shown in FIG. 5.

### 3.2 Operation

A command for instructing the wavelength and the intensity of light to be output is given from the solid state laser control processor 12 (not shown in FIG. 10) to each wavelength tunable semiconductor laser module 111-k. The wavelength and the intensity of light to be output by the wavelength tunable semiconductor laser module 111-k may vary among modules. Each wavelength tunable semiconductor laser module 111-k generates CW laser light having a wavelength and an intensity corresponding to the wavelength instruction and the intensity instruction from the solid state laser control processor 12.

The wavelength control processor 112-1 and the semiconductor laser element 114-1 of the wavelength tunable semiconductor laser module 111-1 shown in FIG. 10 form an example of the “first semiconductor laser device” in the present disclosure, and the output control processor 122-1 and the semiconductor optical amplifier 128-1 form an example of the “first semiconductor optical amplification device” in the present disclosure. The wavelength control processor 112-2 and the semiconductor laser element 114-2 of the wavelength tunable semiconductor laser module 111-2 form an example of the “second semiconductor laser device” in the present disclosure, and the output control processor 122-2 and the semiconductor optical amplifier 128-2 form an example of the “second semiconductor optical amplification device” in the present disclosure. CW laser light output from the semiconductor laser element 114-2 is an example of the “third CW laser light” in the present disclosure, and CW laser light output from the semiconductor optical amplifier 128-2 is an example of the “fourth CW laser light” in the present disclosure.

By multiplexing laser light output from the plurality of wavelength tunable semiconductor laser modules 111-k, an arbitrary spectral waveform can be formed.

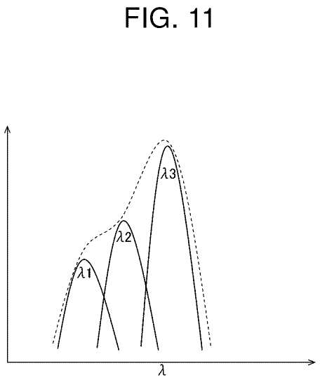

FIG. 11 is a graph showing an example of a multiplexed spectrum. Here, an example in which the number of modules n is 3 is shown, and an example of the multiplexed spectrum obtained by multiplexing laser light having the center wavelength of λk (k=1, 2, 3) output from the three wavelength tunable semiconductor laser modules 111-k (k=1, 2, 3) is shown by a broken line. As shown in FIG. 11, by controlling the center wavelength and the intensity of CW laser light generated in each wavelength tunable semiconductor laser module 111-k, it is possible to obtain a multiplexed spectrum having a desired spectral waveform.

The multiplexed CW laser light is converted into pulse light by the optical parametric amplification device 140 shown in FIG. 10, and then amplified by the laser amplification device 150A. The amplified pulse light is input to the wavelength conversion device 160 and converted into DUV light.

### 3.3 Effect

According to the solid state laser system 102 according to the second embodiment, DUV light having an arbitrary spectral waveform can be obtained by using a plurality of the tunable semiconductor laser modules 111-k. In the solid state laser system 102 according to the second embodiment, similarly to the first embodiment, since CW light is pulsed by pulse excitation light, DUV light having a narrow E95 line width can be generated, and variation in the E95 line width is also small.

### 4. Third Embodiment

### 4.1 Configuration

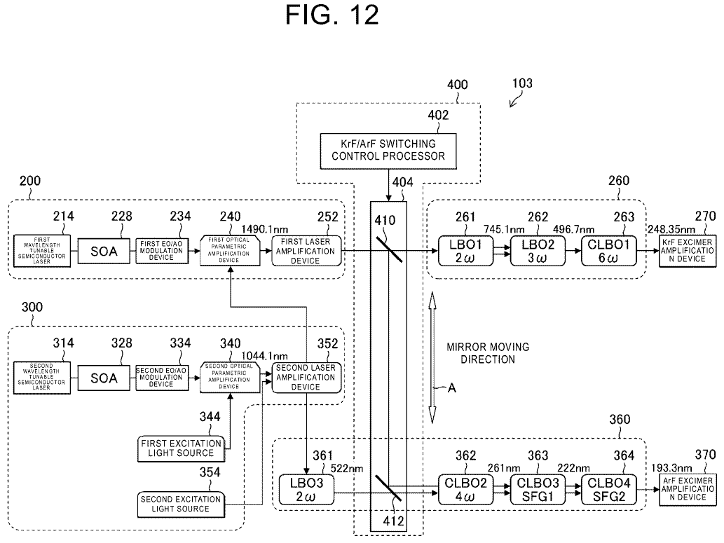

FIG. 12 schematically shows the configuration of a solid state laser system 103 according to a third embodiment. The solid state laser system 103 includes a KrF fundamental wave generation system 200, an ArF fundamental wave generation system 300, a KrF/ArF switching control unit 400, a KrF wavelength conversion device 260, and an ArF wavelength conversion device 360.

The KrF fundamental wave generation system 200 includes a first wavelength tunable semiconductor laser 214 having a wavelength region in a 1400 nm band (1411 nm-1499 nm), a first semiconductor optical amplification device 228, a first EO/AO modulation device 234, a first optical parametric amplification device 240 as a first pulse slicer, and a first laser amplification device 252.

The ArF fundamental wave generation system 300 includes a second wavelength tunable semiconductor laser 314 having a wavelength region in a 1000 nm band (1041 nm-1065 nm), a second semiconductor optical amplification device 328, a second EO/AO modulation device 334, a second optical parametric amplification device 340 as a second pulse slicer, a first excitation light source 344 for the pulse slicer, a second laser amplification device 352, and a second excitation light source 354 for the laser amplification device.

The KrF wavelength conversion device 260 includes a first LBO crystal 261, a second LBO crystal 262, and a first CLBO crystal 263. A KrF excimer amplification device 270 is arranged downstream the KrF wavelength conversion device 260.

The ArF wavelength conversion device 360 includes a third LBO crystal 361, a second CLBO crystal 362, a third CLBO crystal 363, and a fourth CLBO crystal 364. In place of the LBO crystal, an LN crystal, a KTP crystal, or a BBO crystal may be used. In place of the CLBO crystals, BBO crystals may be used. An ArF excimer amplification device 370 is arranged downstream the ArF wavelength conversion device 360.

The KrF/ArF switching control unit 400 includes a KrF/ArF switching control processor 402 and a mirror moving stage 404. The mirror moving stage 404 supports a first mirror 410 and a second mirror 412. The first mirror 410 may be, for example, a high reflection (total reflection) mirror. The second mirror 412 may be, for example, a dichroic mirror. The mirror moving stage 404 is capable of moving the first mirror 410 and the second mirror 412 in the direction of arrow A in FIG. 12.

The mirror moving stage 404 may place the first mirror 410 on the optical path between the first laser amplification device 252 and the KrF wavelength conversion device 260, and place the second mirror 412 on the optical path between the third LBO crystal 361 and the second CLBO crystal 362. Further, the mirror moving stage 404 can retract the first mirror 410 from the optical path between the first laser amplification device 252 and the KrF wavelength conversion device 260, and place the first mirror 410 at a position outside the optical path.

### 4.2 Operation

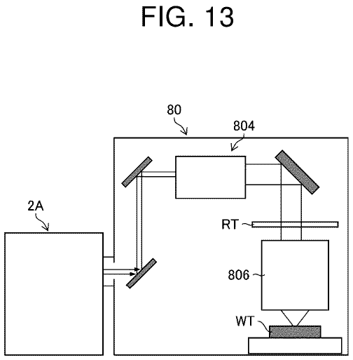

The KrF fundamental wave generation system 200 uses output light of the first wavelength tunable semiconductor laser 214 in the 1400 nm band, operates in a similar manner as the configuration of the first embodiment (FIG. 5), generates pulse light having a wavelength of, for example, 1490.1 nm, and outputs the pulse light to the KrF wavelength conversion device 260. However, the optical parametric amplification device 140 of the first embodiment is configured to excite the optical parametric amplifier 142 with pulse excitation light from the pulse excitation light source 144, whereas the first optical parametric amplification device 240 shown in FIG. 13 performs excitation using pulse light (e.g., wavelength of 1044.1 nm) output from the second laser amplification device 352.

The ArF fundamental wave generation system 300 uses the second wavelength tunable semiconductor laser 314 in the 1000 nm band, generates wavelength tunable CW light, pulses by the second optical parametric amplification device 340, and then performs amplification by the second laser amplification device 352. The second optical parametric amplification device 340 is excited by pulse light of the first excitation light source 344, and the second laser amplification device 352 is excited by pulse light of the second excitation light source 354.

The KrF/ArF switching control processor 402 drives the mirror moving stage 404 in the direction of arrow A in FIG. 12 to switch the guiding destination of the 1400 nm band laser light between the KrF wavelength conversion device 260 and the ArF wavelength conversion device 360.

The positions of the first mirror 410 and the second mirror 412 shown in FIG. 12 represent the mirror positions when the guiding destination of the 1400 nm band laser light is the ArF wavelength conversion device 360. In this case, the first mirror 410 is placed on the optical path of the 1400 nm band laser light output from the first laser amplification device 252, and the second mirror 412 is placed on the optical path between the third LBO crystal 361 and the second CLBO crystal 362 of the ArF wavelength conversion device 360. Further, the second mirror 412 is placed such that the optical axis of laser light having a wavelength of about 522 nm output from the third LBO crystal 361 and the optical axis of the 1400 nm band laser light reflected by the first mirror 410 substantially coincide with each other, and the both are incident on the second CLBO crystal 362.

When the guiding destination of the 1400 nm band laser light is the KrF wavelength conversion device 260, the mirror moving stage 404 is driven to move the first mirror 410 and the second mirror 412 in the direction of arrow A in FIG. 12, so that the first mirror 410 is retracted from the optical path of the 1400 nm band laser light and the second mirror 412 is retracted from the optical path between the third LBO crystal 361 and the second CLBO crystal 362.

The operation of the KrF wavelength conversion device 260 is similar to the operation of the wavelength conversion device 160 described with reference to FIG. 7. The KrF wavelength conversion device 260 performs wavelength conversion on the 1400 nm band laser light and generates DUV light for the KrF laser. DUV light in the KrF laser wavelength region output from the KrF wavelength conversion device 260 is input to the KrF excimer amplification device 270 and amplified by the KrF excimer amplification device 270.

The ArF wavelength conversion device 360 performs wavelength conversion using light output from the second laser amplification device 352 of the ArF fundamental wave generation system 300 and the 1400 nm band light output from the first laser amplification device 252 of the KrF fundamental wave generation system 200 to generate DUV light for the ArF laser. Seed light (e.g., wavelength of 1044.1 nm) pulsed by the second optical parametric amplification device 340 of the ArF fundamental wave generation system 300 is amplified by the second laser amplification device 352 and output to the ArF wavelength conversion device 360 as amplified light.

The amplified light input to the ArF wavelength conversion device 360 is converted into a second harmonic (2ω) having a wavelength of 522 nm by the third LBO crystal 361, and output to the second CLBO crystal 362.

Light having a wavelength of 522 nm output from the third LBO crystal 361 is converted into fourth harmonic (4ω) having a wavelength of 261 nm by the second CLBO crystal 362 and output to the third CLBO crystal 363.

Light having a wavelength of 261 nm output from the second CLBO crystal 362 is converted, by the third CLBO crystal, into light having a wavelength of 222 nm using sum frequency generation (SFG) of light having a wavelength of 261 nm and light having a wavelength of 1490.1 nm which is NIR light generated by the KrF fundamental wave generation system 200, and the converted light is output to the fourth CLBO crystal 364. At this time, light having a wavelength of 1490.1 nm is output light of the first laser amplification device 252, is transmitted to the second CLBO crystal 362 via the first mirror 410 and the second mirror 412, is transmitted through the second CLBO crystal 362, and is input to the third CLBO crystal 363.

Light having a wavelength of 222 nm output from the third CLBO crystal 363 is converted, by the fourth CLBO crystal 364, into light having a wavelength of 193.3 nm using sum frequency generation of light having a wavelength of 222 nm and light having a wavelength of 1490.1 nm, and the converted light is output to the ArF excimer amplification device 370. At this time, light having a wavelength of 1490.1 nm is transmitted through the third CLBO crystal 363 and is input to the fourth CLBO crystal 364. DUV light in the ArF laser wavelength region output from the ArF wavelength conversion device 360 is input to the ArF excimer amplification device 370 and amplified by the ArF excimer amplification device 370.

Here, when the first mirror 410 and the second mirror 412 are moved from the positions of FIG. 12 and amplified light having a wavelength of 1490.1 nm output from the first laser amplification device 252 is input only to the KrF wavelength conversion device 260, the wavelength conversion by the sum frequency generation does not occur in the ArF wavelength conversion device 360, and light having a wavelength of 261 nm output from the second CLBO crystal 362 is output from the ArF wavelength conversion device 360 as it is. In this case, since an oscillator beam steering (OBS) mirror having low reflectance for light having a wavelength of 261 nm is arranged on the optical path between the ArF wavelength conversion device 360 and the ArF excimer amplification device 370, light having a wavelength of 261 nm is hardly output to the ArF excimer amplification device 370. The OBS mirror is an optical axis adjustment mirror for injecting seed light into the ArF excimer amplification device 370.

### 4.3 Effect

According to the configuration according to the third embodiment, by using the KrF fundamental wave generation system 200 including the first wavelength tunable semiconductor laser 214 of the 1400 nm band and the ArF fundamental wave generation system 300 including the second wavelength tunable semiconductor laser 314 of the 1000 nm band, the solid state laser system 103 compatible to both the KrF laser and the ArF laser can be realized.

### 5. Modification of Excimer Amplification Device

The configuration of the excimer amplification device used in combination with the solid state laser system 100, 102, or 103 is not limited to the configuration having a Fabry-Perot resonator such as the excimer amplification device 32 shown in FIG. 1, and may be a configuration having a ring resonator. Further, the excimer amplification device is not limited to have a configuration including an optical resonator, and may be, for example, a multi-pass amplification device such as a three-pass amplification device that performs amplification by reflecting the seed light by a cylindrical mirror and causing the seed light to pass through a discharge space three times.

### 6. Electronic Device Manufacturing Method

FIG. 13 schematically shows a configuration example of the exposure apparatus 80. The exposure apparatus 80 includes an illumination optical system 804 and a projection optical system 806. The laser system 2A is a laser system including the solid state laser system 100 according to the first embodiment in place of the solid state laser system 10 of the laser system 2 described in FIG. 1. The laser system 2A generates pulse laser light using the solid state laser system 100 and the excimer amplification device 32, and outputs the pulse laser light to the exposure apparatus 80. The illumination optical system 804 illuminates a reticle pattern of a reticle (not shown) arranged on a reticle stage RT with laser light incident from the laser system 2A. The projection optical system 806 causes the laser light transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 80 synchronously translates the reticle stage RT and the workpiece table WT to expose the workpiece to the laser light reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure. The laser system 2A may be configured to include the solid state laser system 102 according to the second embodiment or the solid state laser system 103 according to the third embodiment in place of the solid state laser system 100 according to the first embodiment.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser system comprising:
a first semiconductor laser device configured to output first CW laser light;
a first semiconductor optical amplification device configured to amplify the first CW laser light and output second CW laser light;
an optical parametric amplification device configured to amplify the second CW laser light and output first pulse laser light; and
a wavelength conversion device configured to perform wavelength conversion on the first pulse laser light and output second pulse laser light in a deep ultraviolet wavelength region.

2. The laser system according to claim 1,
wherein the first semiconductor laser device outputs the first CW laser light of a single longitudinal mode.

3. The laser system according to claim 2,
wherein the first semiconductor laser device is capable of changing a center wavelength of the first CW laser light.

4. The laser system according to claim 3,
wherein a wavelength of the first CW laser light is in a range of 1411 nm to 1499 nm.

5. The laser system according to claim 3,
wherein a wavelength of the first CW laser light is in a range of 1041 nm to 1065 nm.

6. The laser system according to claim 1,
wherein the first semiconductor optical amplification device outputs the second CW laser light by excitation with a CW current.

7. The laser system according to claim 1,
wherein the optical parametric amplification device outputs the first pulse laser light by excitation with pulse light.

8. The laser system according to claim 7,
further comprising an amplification device arranged on an optical path between the optical parametric amplification device and the wavelength conversion device and configured to amplify the first pulse laser light.

9. The laser system according to claim 7,
wherein the optical parametric amplification device has a multi-stage configuration in which amplification is performed in multi stages using a plurality of optical parametric amplifiers.

10. The laser system according to claim 9,
further comprising a branch optical system configured to branch pulse excitation light and generate a plurality of beams of branched light,
wherein the optical parametric amplification device amplifies the first pulse laser light by exciting each of the plurality of optical parametric amplifiers by the branched light.

11. The laser system according to claim 1,
wherein the optical parametric amplification device includes at least one crystal among a poled lithium niobate crystal and a poled KTP crystal.

12. The laser system according to claim 11,
wherein the crystal is a periodic crystal or a bulk crystal.

13. The laser system according to claim 1,
wherein the wavelength conversion device includes a plurality of nonlinear optical crystals and generates sixth harmonic of the first pulse laser light using the plurality of nonlinear optical crystals.

14. The laser system according to claim 1,
wherein, when a wavelength of the first pulse laser light is in a range of 1489.2 nm to 1491 nm, the wavelength conversion device outputs the second pulse laser light having a wavelength in a range of 248.2 nm to 248.5 nm.

15. The laser system according to claim 1,
wherein the deep ultraviolet wavelength region is an ArF laser wavelength region including 193.3 nm.

16. The laser system according to claim 1,
further comprising an EO modulation device or an AO modulation device on an optical path between the first semiconductor laser device and the optical parametric amplification device.

17. The laser system according to claim 1,
further comprising an excimer amplification device configured to amplify the second pulse laser light.

18. The laser system according to claim 1, further comprising:
a second semiconductor laser device configured to output third CW laser light having a wavelength different from the first CW laser light; and
a second semiconductor optical amplification device configured to amplify the third CW laser light and output fourth CW laser light,
wherein the optical parametric amplification device performs pulse amplification on the second CW laser light and the fourth CW laser light.

19. An electronic device manufacturing method, comprising:
generating laser light using a laser system;
outputting the laser light to an exposure apparatus; and
exposing a photosensitive substrate to the laser light in the exposure apparatus to manufacture an electronic device,
the laser system including:
a first semiconductor laser device configured to output first CW laser light;
a first semiconductor optical amplification device configured to amplify the first CW laser light and output second CW laser light;
an optical parametric amplification device configured to amplify the second CW laser light and output first pulse laser light; and
a wavelength conversion device configured to perform wavelength conversion on the first pulse laser light and output second pulse laser light in a deep ultraviolet wavelength region.
